(19) United States
(12) Patent Application Publication
(10) Pub. No.: US 2003/0203524 A1
(43) Pub. Date: Oct. 30, 2003

(54) Process for packaging of light emitting devices using a spin-on-glass material

(76) Inventors: Faramarz Farahi, Charlotte, NC (US); Pedram Leilabady, Charlotte, NC (US); Ramazan Benrashid, Charlotte, NC (US); Patrick Moyer, Charlotte, NC (US)

Correspondence Address: PEDRAM LEILABADY, WAVEGUIDE SOLUTIONS, INC, SUITE 200, 6125 LAKEVIEW ROAD, CHARLOTTE, NC, 28269, US

(21) Appl. No.: 10/436,531

(22) Filed: May 14, 2003

Related U.S. Application Data
(63) Continuation-in-part of application No. 09/803,342, filed on Mar. 9, 2001.

(51) Int. Cl. H01L 21/00

(52) U.S. Cl. 438/26

(57) ABSTRACT

The present invention relates to a process for controlling and/or enhancing the light emission and/or amplitude of a light-emitting device comprising depositing on the surface of such light-emitting device a spin-on glass material at a process temperature of less than 225° C., wherein the spin-on glass material is directly patternable as a negative photoresist. The spin-on glass material is directly patternable using standard photolithography methods and may be used for the purpose of patterning mechanical stand-offs for light emitting device-packaging purposes.

### CROSS-REFERENCE TO RELATED APPLICATIONS

This application claims the benefit of priority under 35 U.S.C. 119(c) to U.S. Provisional Application No. 60/378,825 filed May 9, 2003. This application also claims priority under 35 U.S.C. 120 and is a continuation-in-part of U.S. application Ser. No. 09/803,342.

### FIELD OF THE INVENTION

The present invention relates to a light-emitting device, such as a light emitting diode (LED) or a vertical cavity surface emitting laser (VCSEL) and, specifically, to a process for the packaging or encapsulating of such a light-emitting device.

### BACKGROUND OF THE INVENTION

A light-emitting diode is an optoelectronic device (usually a semiconductor chip) that emits visible light when an electric current is passed through it. The manufacturing process for LEDs is very similar to that used to fabricate electronic integrated circuits—utilizing the same equipment, the same materials, with the same large-scale manufacturing cost structure, etc.

One type of high brightness LED uses Gallium Nitride (GaN). GaN is a crystal, the fundamental ingredient of a semiconductor, with band gap characteristics specifically advantageous for many visible short wavelength and ultraviolet LED applications. GaN was first successfully produced for High Brightness LEDs via MOCVD epitaxy on Al₂O₃ (Sapphire) and this combination continues today in large-scale production from an increasing supplier base. Subsequently, GaN LEDs have also been produced on SiC (Silicon carbide) substrates as well and are currently in large-scale production, albeit with somewhat lower brightness results. Other materials as well, each selected by device designers (both photonic and/or electronic) that base their selection upon the individual materials' physical properties, are also in development for both LEDs and electronic components. For High Brightness LEDs, the current production platforms are Sapphire and Silicon Carbide. Others Substrates: Silicon, Diamond, Gallium Nitride, GaAs, ZnO, Spinel (MgAl₂O₄), Lithium Gallium Oxide and other materials have been used to work with GaN or are in development.

Packaging engineering of LED semiconductors, is a key contributor to producing better component designs that perform more efficiently in a wide variety of operational and environmental conditions, than current conventional formats. Packaging engineering will be of increased importance as demand for LEDs to fulfill new, higher performance, higher brightness applications continues to manifest and gain momentum. Current packaging performance efficiencies, compared to LED die performance attributes, clearly shows that most conventional packages existing to date, are inadequate for the demands of many current and future applications.

VCSEL technology involves one approach to the fabrication of semiconductor lasers. By constructing the laser optical cavity in the direction perpendicular to the active layer, a device is created which has the attributes of an LED in terms of processing plus the optical output properties of a laser diode. VCSELs are fabricated using either ion implantation or oxide confinement. The ion implantation process creates a resistive area that funnels the current into the active region. Oxide confinement provides both current guiding and index guiding for improved efficiency. The advantages of VCSEL are: high power conversion efficiency, low threshold currents (less than 1 mA), extremely focused, symmetrical circular beam profile, ability to test devices on the wafer, ease of fabrication into arrays, processing similar to LEDs, very stable over temperature performance, low EMI/RFI, high reliability and multiple packaging options.

LEDs are commonly used in communications, a number of industrial instruments, computer/office equipment, and in many consumer electronic devices. The LED market is poised to experience explosive growth due to many promising advances in LED technology and the resulting variety of new applications utilizing this technology. In addition, economic drivers such as the recent energy crisis and the increased worldwide use of mobile phones and personal data assistants are expected to lead to an exceptional growth rate in the overall LED market. The worldwide market for LEDs was about $2.9 billion in 2000 and is expected to grow at about 17% each year, to reach nearly $5.0 billion in 2005.

Currently, LED manufacturers use a polymeric resin encapsulant material for packaging the active chips, and a Cerium (Ce) activated and Gadolinium (Gd) doped Yttrium-Aluminum-Garnet (YAG) phosphor is used to generate white light emission. This material is typically referred to as a Ce:YAG phosphor, and the white light emission results from ultraviolet (UV) LED pumping, which is typically around 450 nm (nanometer) LED emission, to generate white light appearance. Chemically altering the transparent resin with the trivalent ion of Praesodymium (Pr) has also been utilized for the purpose of improving the red response of the Ce:YAG phosphor. Other dopants such as nano-particle quantum dots could also be used. The combination of nano-particle quantum dots and phosphor dopants provides the maximum flexibility in deriving the desired color produced by the LED.

U.S. patent applications Ser. Nos. 2002/0084745A1 and 2002/0085601A1 both relate to an LED with a dielectric phosphor powder. The applications disclose dopant percentages (e.g. the phosphor is 2 weight %-25 weight % concentration), phosphor particle size distribution, specific phosphor dopants, as well as an epoxy encapsulation covered with the dielectric phosphor powder. Further, the applications describe this phosphor powder imbedded into the epoxy encapsulant.

U.S. patent application Ser. No. 2002/0105266A1 relates to an LED with a phosphor layer, comprising a phosphor and a coating, the coating being water resistant for a prolonged diode life, wherein the LED chip is encased within an epoxide material. WO 00219440A1 discloses a light emitting structure wherein the active device is encapsulated within a material comprising an epoxy resin and a catalyst, while EP 1081771A2 relates to the encapsulation of the LED device with an optical grade silicone gel.

One serious problem with the current encapsulation and packaging materials for light emitting devices is material aging, which results from degradation or a visible browning of the material upon prolonged UV, purple, and/or blue light exposure. In addition, the present technology for producing a packaged or encapsulated light-emitting device is both expensive and labor intensive. The present invention provides a number of advantages over current methods utilized in this industry. They include utilizing a dielectric packaging material that: (1) may be deposited at very low cost; (2) is similar to glass in that it is primarily silicon dioxide, which has proven itself in many similar applications; (3) it can be doped with different materials for optical, electrical, mechanical, and/or thermal purposes; (4) it is directly patternable using photolithography, because it behaves as a negative photoresist; (5) it's thickness can be controlled from submicron to more than 100 microns; and (6) it can be directly processed on top of an existing electronic and/or optoelectronic wafer.

### SUMMARY OF THE INVENTION

The present invention relates to a process for controlling and/or enhancing the light emission and/or amplitude of a light-emitting device comprising depositing on the surface of such light-emitting device a spin-on glass material at a process temperature of less than 225° C., wherein the spin-on glass material is directly patternable as a negative photoresist. The process is capable of providing a mechanical standoff for light-emitting device packaging by patterning the spin-on glass material. The light-emitting device is preferably a light-emitting diode or a vertical cavity surface-emitting laser. The process may further comprise patterning the spin-on glass material as a negative photoresist, and the spin-on glass material is preferably capable of hosting a dopant material. The process may also comprise doping the spin-on glass material with a phosphor-containing dopant material, nano-particle quantum dots or a combination of nano-particle quantum dots and phosphor dopant materials. The process may further comprise exciting the spin-on glass material at 400 nm to 470 nm light wavelength, thereby providing a primary light that is capable of generating secondary light that creates a white light source. The process may also comprise doping the spin-glass material with a dopant material that provides controlled secondary emission in other spectral wavelengths. The subject process preferably provides packaging for the light-emitting device by utilizing the spin-on glass material in a manner such that the light transmission capability of the packaging will not considerably degrade under constant long-term ultra-violet illumination.

In the present process a spin-on glass material may be utilized as a matrix for hosting a material dopant in a process for producing a packaged or encapsulated light-emitting device. A dopant, such as a phosphor, can be used to enhance and/or control the light emission color and/or amplitude of the light-emitting device, such as an LED or a VCSEL. Also described is a method for utilizing the spin-on glass material to provide packaging for the light-emitting device, such that the light transmission capability of the packaging will not considerably degrade under constant long-term ultra-violet illumination.

The preferred spin-on glass-like material utilized for the purpose of packaging or encapsulating a light-emitting device will not degrade appreciably under long-term exposure to UV light. That is, the SOG material utilized in the present process provides a packaged light-emitting device wherein the packaging has higher resistance to degradation of light transmission via constant light-emitting device operation. For example, the packaged light-emitting device produced by the process of the present invention maintains a larger output power under UV light operation without degradation, when compared with current polymeric packaging materials and encapsulants.

### DETAILED DESCRIPTION OF THE INVENTION

All embodiments of the present invention utilize a hybrid glass/polymer sol-gel material, which is called a spin-on-glass (SOG) material. The subject invention is not limited to a particular SOG material, but it requires a SOG material that: (1) can be utilized at a low process temperature (<225° C.); and (2) has the ability to be integrated into a traditional semiconductor production process to thereby provide a packaged or encapsulated light-emitting device. An example of such a hybrid Sol-Gel material is described in a paper by Fardad et al. (M. Amir Fardad, Oleg V. Mishechkin, and Mahmoud Fallahi, “Hybrid Sol-Gel Materials for Integration of Optoelectronic Components”, Journal of Lightwave Technology, Vol. 19, No. 1, January 2001). Details of the fabrication of the material and the process conditions for producing such a material can be found in this reference.

The process of the present invention, which relates to a process that uses the SOG material to provide a packaged or encapsulated a light-emitting device, such as an LED or a vertical cavity surface emitting laser (VCSEL) has two fundamental requirements. These process requirements are: (1) the use of the SOG material matrix as a host material for a dopant, such as a phosphor, for controlling and/or enhancing the light emission color or amplitude of the light-emitting device and (2) the use of the SOG material for packaging or encapsulation purposes (e.g., a dielectric insulator buffer, a patternable mechanical stand-off, or a non-degradable encapsulant). Current packaging or encapsulant materials for light emitting devices are polymeric and degrade under constant exposure to ultraviolet light, such as that emitted by the light emitting device.

Doping the SOG material with a phosphor dopant material will result in white light emission when a 400 nm-480 nm LED is coated with the doped SOG material. The SOG material may be deposited onto the light-emitting device in a drop-like fashion, or it may be spin-coated directly on top of the wafer and/or patterned before the wafer is diced. The thickness of the droplet, the dopant density, and the particular SOG host material utilized are all application specific parameters, and are controllable using the process of the present invention. Examples of such phosphor dopants include phosphor-doped YAG and other similar phosphor-doped complexes.

In another embodiment of the invention, doping the SOG material with a quantum dot dopant material will result in the ability to alter the emission wavelength of the light emitting device. Quantum dots are tunable band-gap semiconductor nanocrystals. The performance of quantum dots is degraded when exposed to moisture. Conventional encapsulant materials such as silicones and epoxies do not provide adequate moisture protection for quantum dots. As a result their application in solid state lighting and telecommunication has been hindered. The SOG described in this invention provides the necessary moisture resistance for quantum dots to be efficiently deployed in such photonic applications. The quantum doped SOG material may be deposited onto the light-emitting device in a drop-like fashion, or it may be spin-coated directly on top of the wafer and/or patterned before the wafer is diced. Doing so forms a “wavelength converter film” which can convert blue or UV diode emission into any longer wavelength. Since the band-gap can be tuned to match the emission of the source, enhanced energy conversion efficiencies can be obtained. The thickness of the droplet, the dopant density, and the particular SOG host material utilized are all application specific parameters, and are controllable using the process of the present invention. Examples of such quantum dot dopants include lead selenide (PbS) and cadmium selenide (CdS).

In another preferred embodiment of the invention, the SOG material may be patterned using standard photolithography techniques, because the SOG material behaves as a negative photoresist. In other words, the light-sensitive photoresist composition, when exposed to a light pattern, undergoes a chemical change so that the exposed portions of the photoresist are insoluble in the solution used to develop or wash away the soluble unexposed portions of the photoresist composition. This characteristic, as well as the fact that it is predominantly silicon dioxide, makes it a good material for packaging, such as a mechanical standoff or an LED encapsulation material. The SOG material may be spin-coated onto the wafer for patterning or it can be poured into an encapsulation cup before it is subsequently fully cured, either thermally or using ultra-violet light.

### DESCRIPTION OF THE DRAWINGS

FIG. 1 schematically depicts a light-emitting device, such as an LED, consisting of an electrically grounded casing (1), wherein the light emitting active chip (2) is electrically connected by a bond wire (3).

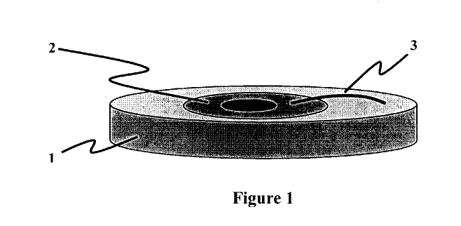

FIG. 2 schematically depicts a light emitting device, such as an LED, consisting of an electrically grounded casing (1), wherein the light emitting active chip (2) is electrically connected by a bond wire (3), and a droplet of spin-on glass material (4) is used to aid in the packaging of the device. In the embodiment illustrated in this figure, the SOG material may or may not be used as a host material for a dopant (5), such as a phosphor.

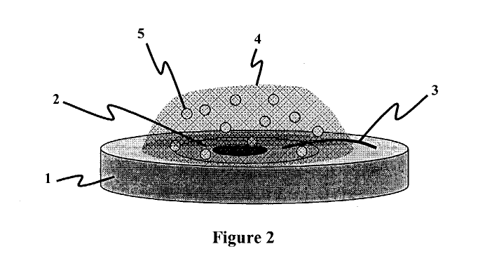

FIG. 3 schematically depicts a light emitting device, such as an LED, consisting of an electrically grounded casing (1), wherein the light emitting active chip (2) is electrically connected by a bond wire (3), and a photolithographically patterned and developed spin-on glass material (6) is used to aid in the packaging of the device. In the embodiment illustrated in this figure, the spin-on glass material may or may not be used as a host material for a dopant (5), such as a phosphor.

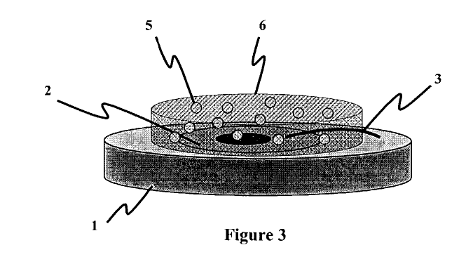

1. A process for controlling and/or enhancing the light emission and/or amplitude of a light-emitting device comprising depositing on the surface of such light-emitting device a spin-on glass material at a process temperature of less than 225° C., wherein the spin-on glass material is directly patternable as a negative photoresist.

2. The process of claim 1, further comprising providing a mechanical standoff for light-emitting device packaging by patterning the spin-on glass material.

3. The process of claim 1, wherein the light-emitting device is a light-emitting diode or a vertical cavity surface emitting laser.

4. The process of claim 1, further comprising patterning the spin-on glass material as a negative photoresist.

5. The process of claim 1, wherein the spin-on glass material is capable of hosting a dopant material.

6. The process of claim 4, comprising doping the spin-on glass material with a phosphor-containing dopant material.

7. The process of claim 4, further comprising doping the spin-on glass material with nano-particle quantum dots.

8. The process of claim 4, further comprising doping the spin-on glass material with a combination of nano-particle quantum dots and phosphor dopant materials.

9. The process of claim 5, further comprising exciting the spin-on glass material at 400 nm to 470 nm light wavelength and thereby providing a primary light that is capable of generating secondary light that creates a white light source.

10. The process of claim 4, further comprising doping the spin-glass material with a dopant material that provides controlled secondary emission in other spectral wavelengths.

11. The process of claim 1, further comprising providing packaging for the light-emitting device by utilizing the spin-on glass material in a manner such that the light transmission capability of the packaging will not considerably degrade under constant long-term ultra-violet illumination.
